(19) United States
(12) Patent Application Publication
(10) Pub. No.: US 2021/0238456 A1
(43) Pub. Date: Aug. 5, 2021

(54) FILLER-CONTAINING FILM

(71) Applicant: DEXERIALS CORPORATION, Tokyo (JP)

(72) Inventor: Makoto MATSUBARA, Utsunomiya-shi (JP)

(73) Assignee: DEXERIALS CORPORATION, Tokyo (JP)

(21) Appl. No.: 17/059,287

(22) PCT Filed: Jun. 6, 2019
(86) PCT No.: PCT/JP2019/022492

§ 371 Date: Nov. 27, 2020

(30) Foreign Application Priority Data
Jun. 6, 2018 (JP) 2018-109087
Jun. 6, 2019 (JP) 2019-105900

(51) Int. Cl. C09J 11/04; H01R 4/04; H01L 23/00; C09J 7/35; C09J 7/10; C09J 171/12; C09J 163/00

(52) U.S. Cl. CPC C09J 11/04; H01R 4/04; H01L 24/29; H01L 24/32; C09J 7/35; C08K 3/013; C09J 171/12; C09J 163/00; H01L 2224/29499; H01L 2224/32505; C09J 7/10

(57) ABSTRACT

A filler-containing film that holds fillers and a fine solid in an insulating resin layer and a predetermined arrangement of the fillers is repeated as viewed in a plan view has a proportion of 300% or less where the proportion is a repeat pitch of the fillers after thermocompression bonding to that before thermocompression bonding during thermocompression bonding under a predetermined thermocompression bonding condition with the filler-containing film held between smooth surfaces. A method of producing the filler-containing film includes the steps of: forming an insulating resin layer on a release substrate; pushing fillers from a surface on a side opposite to the release substrate of the insulating resin layer; and layering the insulating resin layer containing the fillers pushed and another insulating resin layer. This filler-containing film suppresses disorder of arrangement of fillers during thermocompression bonding of the film to an article.

### TECHNICAL FIELD

The present invention relates to a filler-containing film.

### BACKGROUND ART

Filler-containing films that contain fillers dispersed in a resin layer have been used in various use applications such as matte films, capacitor films, optical films, labeling films, antistatic films, conductive films, and anisotropic conductive films (Patent Literature 1, Patent Literature 2, Patent Literature 3, and Patent Literature 4). When a filler-containing film is thermocompression-bonded to an article and used, it is desirable to suppress an unnecessary flow of a resin that forms the filler-containing film during thermocompression bonding and suppress uneven distribution of fillers from the viewpoint of optical characteristics, mechanical characteristics, or electrical characteristics. In particular, when a filler-containing film that contains conductive particles as fillers is used as an anisotropic conductive film for use in mounting electronic components, the conductive particles are densely dispersed in an insulating resin layer so that the filler-containing film can be adapted in high-density mounting of the electronic component. In this case, the conductive particles are unnecessarily carried by a resin flow during mounting of the electronic component, and unevenly distributed between terminals, thereby causing short circuit. Therefore, it is desirable to suppress such resin flow.

On the other hand, a fine solid such as a melt viscosity modifier or a thixotropic agent is added to an insulating resin layer (Patent Literature 5 and Patent Literature 6).

In order to improve conductive particles capturing properties at terminals of an electronic component when conductive particles are densely dispersed in the insulating resin layer and to suppress short circuit, the conductive particles are regularly disposed (Patent Literature 5 and Patent Literature 6).

### CITATION LIST

### Patent Literature

Patent Literature 1: Japanese Patent Application Laid-Open No. 2006-15680

Patent Literature 2: Japanese Patent Application Laid-Open No. 2015-138904

Patent Literature 3: Japanese Patent Application Laid-Open No. 2013-103368

Patent Literature 4: Japanese Patent Application Laid-Open No. 2014-183266

Patent Literature 5: Japanese Patent No. 6187665

Patent Literature 6: Japanese Patent Application Laid-Open No. 2016-031888

### SUMMARY OF INVENTION

### Technical Problem

The insulating resin layer that contains the fine solid is generally formed by applying an insulating resin layer-forming composition that contains the fine solid dispersed therein, and drying the composition. However, when the insulating resin layer that contains the fine solid in a high concentration is formed by applying the insulating resin layer-forming composition, and drying the composition, a dried surface of the insulating resin layer (i.e., a surface of a coating layer of the insulating resin layer-forming composition from which a solvent contained in the composition is evaporated) is roughened due to the fine solid. This may cause the adhesiveness of the insulating resin layer to decrease, temporary pressure bonding during mounting of an electronic component to be unevenly achieved, and the bonding state to be unstable. Further, thermocompression bonding during final pressure bonding is not evenly achieved, and the arrangement of conductive particles regularly arranged in the insulating resin layer is disordered. Therefore, improvement in the conductive particles capturing properties at the terminals of the electronic component and suppression of short circuit may be adversely affected. This problem becomes noticeable especially when the electronic component is downsized as well as the terminals are narrowed. A problem of decrease in the adhesiveness of a surface of the filler-containing film that is thinner may become more noticeable than the filler-containing film that is thick.

Therefore, a problem to be solved by the present invention is to suppress disorder of arrangement of fillers during thermocompression bonding of a filler-containing film to an article in the filler-containing film in which a moderate amount of fine solid added is dispersed in an insulating resin layer and the fillers such as conductive particles are regularly arranged by repeating a predetermined arrangement.

### Solution to Problem

The present inventor has found that when a filler-containing film in which fillers such as conductive particles and a fine solid that is made of a material different from that of the filler are held in an insulating resin layer is produced by steps of applying an insulating resin layer-forming composition containing the fine solid to form the insulating resin layer, and pushing the fillers into the insulating resin layer, a dried surface of the insulating resin layer is not exposed from a surface of the filler-containing film, so that disorder of the arrangement of the fillers during thermocompression bonding of the filler-containing film to an article is decreased. Thus, the present inventor has completed the present invention.

That is, the present invention provides a filler-containing film that holds fillers and a fine solid that is made of a material different from that of the filler in an insulating resin layer and in which a predetermined arrangement of the fillers is repeated as viewed in a plan view. In the filler-containing film, a proportion of a repeat pitch of the fillers after thermocompression bonding to that before thermocompression bonding during thermocompression bonding under a predetermined thermocompression bonding condition with the filler-containing film held between smooth surfaces is 300% or less. In particular, the present invention provides an aspect in which the insulating resin layer is formed from a layered body of two insulating resin layers and an aspect in which a low-viscosity resin layer having the lowest melt viscosity at a range of 30 to 200° C. that is lower than that of the insulating resin layer is layered on the insulating resin layer.

The present invention provides, as a first producing method of the filler-containing film, a producing method of the filler-containing film including the steps of:

applying an insulating resin layer-forming composition containing a fine solid to a release substrate to form an insulating resin layer on the release substrate;

pushing fillers from a surface on a side opposite to the release substrate of the insulating resin layer; and

layering the insulating resin layer containing the fillers pushed and another insulating resin layer that is different from the insulating resin layer with the release substrates thereof facing outward.

As a second producing method, the present invention provides a producing method of the filler-containing film including the steps of:

applying an insulating resin layer-forming composition containing a fine solid to a release substrate to form an insulating resin layer on the release substrate;

layering two insulating resin layers with the release substrates thereof facing outward to form a layered body of the insulating resin layers; and

pushing fillers into the layered body of the insulating resin layers.

As a third producing method, the present invention provides a producing method of the filler-containing film including the steps of:

applying an insulating resin layer-forming composition containing a fine solid to a release substrate to form an insulating resin layer on the release substrate;

applying a composition for formation of a low-viscosity resin layer having the lowest melt viscosity at a range of 30 to 200° C. that is lower than that of the insulating resin layer to a release substrate to form a low-viscosity resin layer on the release substrate;

layering the insulating resin layer and the low-viscosity resin layer with the release substrates thereof facing outward to form a layered body of the insulating resin layer and the low-viscosity resin layer; and

peeling the release substrate of the insulating resin layer and pushing fillers from a surface of the insulating resin layer from which the release substrate has been peeled.

As a fourth producing method, the present invention provides a producing method of the filler-containing film including the steps of:

applying an insulating resin layer-forming composition containing a fine solid to a release substrate to form an insulating resin layer on the release substrate;

applying a composition for formation of a low-viscosity resin layer having the lowest melt viscosity at a range of 30 to 200° C. that is lower than that of the insulating resin layer to a release substrate to form a low-viscosity resin layer on the release substrate;

pushing fillers into a surface on a side opposite to the release substrate of the insulating resin layer; and

layering the insulating resin layer containing the fillers pushed and the low-viscosity resin layer formed on the release substrate with the release substrates thereof facing outward.

### Advantageous Effects of Invention

According to the producing method of the filler-containing film of the present invention, the surface of the filler-containing film may not be roughened although the insulating resin layer contains a moderate amount of fine solid added in terms of viscosity adjustment, or the like. This may allow the surface of the filler-containing film to have good adhesiveness to a variety of articles. Accordingly, the fillers in the filler-containing film that has been bonded to an article by thermocompression bonding can be mostly maintained in a predetermined arrangement before thermocompression bonding.

For example, when the fillers in the filler-containing film of the present invention are conductive particles, and the filler-containing film of the present invention is used for anisotropic conductive connection between electronic components, good temporary pressure bonding can be achieved, and the arrangement of the conductive particles is unlikely to be disordered even in final pressure bonding. Therefore, the conductive particles can be mostly maintained in the predetermined arrangement before thermocompression bonding. Accordingly, even when the electronic components are downsized as well as terminals are narrowed, good anisotropic conductive connection between the electronic components can be achieved.

### BRIEF DESCRIPTION OF DRAWINGS

FIG. 1A is a plan view illustrating a filler disposition of a filler-containing film 1A according to an example.

FIG. 1B is a cross-sectional view of the filler-containing film 1A according to the example.

FIG. 2A is a view illustrating a producing method of the filler-containing film 1A according to the example.

FIG. 2B is a view illustrating the producing method of the filler-containing film 1A according to the example.

FIG. 2C is a view illustrating the producing method of the filler-containing film 1A according to the example.

FIG. 2D is a view illustrating the producing method of the filler-containing film 1A according to the example.

FIG. 2E is a view illustrating the producing method of the filler-containing film 1A according to the example.

FIG. 2F is a view illustrating the producing method of the filler-containing film 1A according to the example.

FIG. 3 is a cross-sectional view of a filler-containing film 1B according to an example.

FIG. 4A is a view illustrating a producing method of the filler-containing film 1B according to the example.

FIG. 4B is a view illustrating the producing method of the filler-containing film 1B according to the example.

FIG. 4C is a view illustrating the producing method of the filler-containing film 1B according to the example.

FIG. 5 is a cross-sectional view of a filler-containing film 1C according to an example.

FIG. 6 is a view illustrating a producing method of the filler-containing film 1C according to the example.

FIG. 7 is a cross-sectional view of a filler-containing film 1D according to an example.

FIG. 8A is a view illustrating a producing method of the filler-containing film 1D according to the example.

FIG. 8B is a view illustrating the producing method of the filler-containing film 1D according to the example.

FIG. 8C is a view illustrating the producing method of the filler-containing film 1D according to the example.

FIG. 9 is a view illustrating a producing method of the filler-containing film 1E according to an example.

FIG. 10A is a view illustrating a producing method of the filler-containing film 1E according to the example.

FIG. 10B is a view illustrating the producing method of the filler-containing film 1E according to the example.

FIG. 10C is a view illustrating the producing method of the filler-containing film 1E according to the example.

FIG. 11 is a perspective view of a sample for an adhesion strength test.

FIG. 12 is a view illustrating a method for the adhesion strength test.

### DESCRIPTION OF EMBODIMENTS

Hereinafter, an example of a filler-containing film of the present invention will be described in detail with reference to the drawings. In the drawings, the same reference numerals denote the same or similar elements.

### <Overall Configuration of Filler-Containing Film 1A>

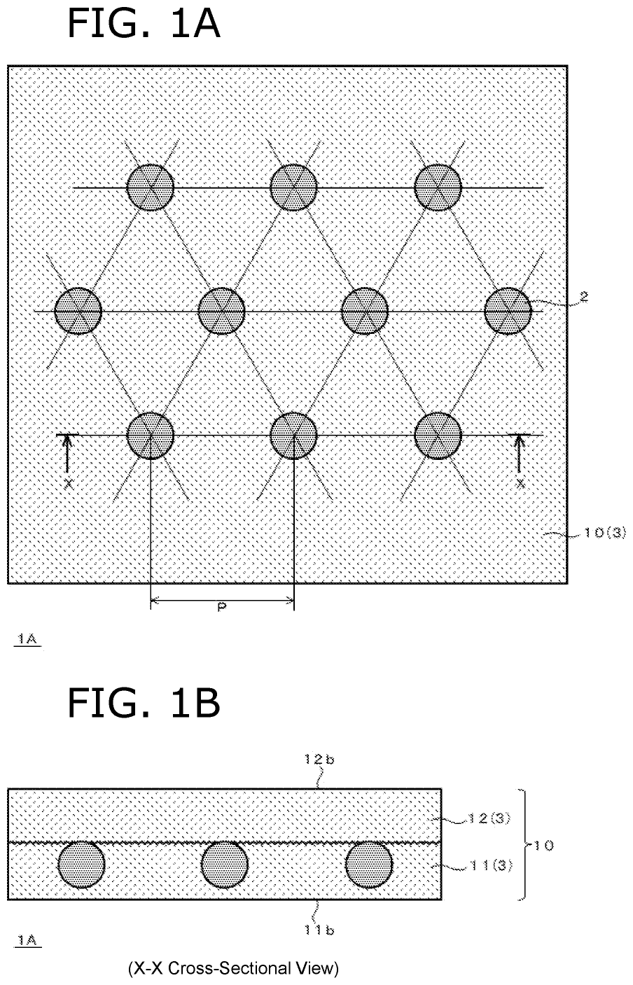

FIG. 1A is a plan view illustrating a filler disposition of a filler-containing film 1A according to an example, and FIG. 1B is an X-X cross-sectional view thereof. The filler-containing film 1A contains conductive particles as fillers 2, and is used as an anisotropic conductive film. The conductive particles are held in an insulating resin layer 10 in a regular disposition in which a predetermined arrangement is repeated. The insulating resin layer 10 contains a fine solid 3 in addition to the fillers 2. When a conventional filler-containing film is thermocompression-bonded while being held between smooth surfaces as described below, the regular disposition of fillers before thermocompression bonding is spread after thermocompression bonding, the repeat pitch of arrangement after thermocompression bonding is made wider than that before thermocompression bonding, a variation of the repeat pitch is increased, and the arrangement of the fillers is disordered. In the filler-containing film of the present invention, on the other hand, the movement of fillers is small, the arrangement is slightly disordered, and the proportion of the repeat pitch of the fillers after thermocompression bonding to that before thermocompression bonding is 300% or less, preferably 250% or less, and more preferably 200% or less. Specifically, a relative positional relationship of the filler disposition before and after thermocompression bonding is maintained according to the filler-containing film of the present invention, and therefore the closest distance between centers of the fillers after thermocompression bonding can be 3 or less times, 2.5 or less times, or 2 or less times the closest distance between the centers of the fillers before thermocompression bonding.

For the filler-containing film of the present invention, there is a thermocompression bonding condition where the proportion of the repeat pitch of the fillers after thermocompression bonding to that before thermocompression bonding is equal to or less than the aforementioned value. This is considered because according to a producing method of the filler-containing film of the present invention, the surface of the filler-containing film 1A is a peeled surface that is peeled from a release substrate, and therefore the surface of the filler-containing film 1A is not roughened regardless of a large amount of the fine solid 3 contained in the insulating resin layer 10, and is a smooth surface; when the smooth surface is bonded to an article and pressurized under heating, the filler-containing film is evenly pressed, even application of a pressing force to the fillers regularly arranged in the film is not impaired by the fine solid, and uneven disorder of the arrangement of the fillers is suppressed; and thus, the disposition of the fillers after pressurization under heating is a disposition in which an original arrangement is evenly extended and a portion where the proportion of the repeat pitch of the fillers after thermocompression bonding to that before thermocompression bonding is locally increased is decreased.

A decrease in the movement of the fillers and the disorder of the arrangement of the fillers that are caused by thermocompression bonding becomes more noticeable when the thickness of a resin layer forming the filler-containing film is small.

When thermocompression bonding is not performed at the smooth surface, the movement of the fillers and the disorder of the arrangement of the fillers that are caused by thermocompression bonding are made uneven. Therefore, when the filler-containing film is configured as an anisotropic conductive film, and a fine-pitch bump arrangement is thermocompression-bonded using the anisotropic conductive film, the disorder of the filler arrangement may be relatively increased.

### <Filler>

In the present invention, the fillers 2 are appropriately selected according to the performance required for hardness and the use application such as optical performance, from well-known inorganic fillers (metal particles, metal oxide particles, metal nitride particles, etc.), organic fillers (resin particles, rubber particles, etc.), and fillers in which an organic material and an inorganic material are mixed (for example, particles (metal-coated resin particles), in which the core is formed of a resin material and the surface is metal-plated, particles in which insulating fine particles are adhered to the surface of conductive particles, particles in which surfaces of conductive particles are insulated, etc.), depending on the use application of the filler-containing film. For example, in an optical film or a matte film, a silica filler, a titanium oxide filler, a styrene filler, an acrylic filler, a melamine filler, and various titanates may be used. In a capacitor film, titanium oxide, magnesium titanate, zinc titanate, bismuth titanate, lanthanum oxide, calcium titanate, strontium titanate, barium titanate, barium zirconate titanate, lead zirconate titanate, and mixtures thereof may be used. In an adhesive film, polymer-based rubber particles, silicone rubber particles, and the like may be contained. Conductive films and anisotropic conductive films may be allowed to contain conductive particles. Examples of the conductive particles may include metal particles of nickel, cobalt, silver, copper, gold, palladium, and the like, alloy particles of solder and the like, metal-coated resin particles, and metal-coated resin particles having insulating fine particles attached to a surface thereof. Two types or more of them may be used in combination. Among them, metal-coated resin particles are preferable from the viewpoint that the contact with a terminal is easily maintained by repulsion of the resin particles after connection, and the conduction performance is stabilized. Further, the surface of the conductive particles may be subjected to an insulation treatment by known techniques where the insulation treatment does not impair the conduction characteristics.

### <Particle Diameter of Filler>

In the present invention, the particle diameter of the fillers 2 can be set according to the use application of the filler-containing film. For example, when the filler-containing film is used as an anisotropic conductive film, the particle diameter of the fillers is preferably 1 μm or more, and more preferably 2.5 μm or more in order to improve the pushing precision of the fillers during production of the filler-containing film. In order to suppress an influence of shifting of the fillers during production of the filler-containing film, the particle diameter is preferably 200 μm or less, and more preferably 50 μm or less. Herein, the particle diameter means an average particle diameter. The average particle diameter of the fillers in the filler-containing film can be determined from a planar image or a cross-sectional image. The average particle diameter of the fillers that are original particles before addition to the filler-containing film can be determined with a wet-type flow particle diameter and shape analyzer FPIA-3000 (manufactured by Malvern Instruments Ltd.). When fine particles such as insulating fine particles are attached to the fillers, the particle diameter of the fillers except for the fine particles is used as the particle diameter.

The variation of a particle diameter D of the fillers in the filler-containing film is preferably 20% or less of a CV value (standard deviation/average). In this case, the filler-containing film tends to be evenly pressed during pressure bonding of the filler-containing film to an article, and local concentration of a pressing force can be prevented. Therefore, when the filler-containing film is configured as an anisotropic conductive film, the stability of connection can be improved, and a connection state can be precisely evaluated after connection by observation of an impression and a holding state of the fillers. Specifically, in an inspection after anisotropic conductive connection between electronic components using the anisotropic conductive film, a connection state can be precisely confirmed by observation of an impression and a holding state of the conductive particles even when the terminal size is relatively large (FOB, etc.) or relatively small (COG, etc.). Therefore, the inspection after anisotropic conductive connection is easy, and improvement in productivity in a connection process can be expected.

### <Filler Arrangement>

As viewed in a plan view of the filler-containing film of the present invention, the fillers are in a regular disposition in which a predetermined arrangement is repeated. In the filler-containing film 1A according to the example illustrated in FIG. 1A, the disposition of the fillers 2 is a hexagonal lattice arrangement. Examples of the regular disposition of the fillers in the present invention may include lattice arrangements such as a tetragonal lattice, a rectangular lattice, and an orthorhombic lattice. Multiple different lattices may be combined. Particle rows in which the fillers are linearly arranged at predetermined intervals may be disposed in parallel at predetermined intervals. A region where the fillers are densely disposed and a region where the fillers are coarsely disposed may be regularly repeated. A unit where the fillers are in contact with each other may form a regular repeat unit of the fillers. When the filler-containing film is used as an anisotropic conductive film, it is more preferable that the conductive particles be regularly arranged in non-contact with each other in terms of not only achieving capturing stability at the terminals but also suppressing short circuit. Whether the fillers are regularly arranged can be determined, for example, by observing whether a predetermined disposition of the fillers is repeated in a long-side direction of the film (a winding direction when the filler-containing film is wound into a wound body).

When the fillers are regularly arranged, the lattice axis or arrangement axis of the arrangement may be parallel or crossed with at least one of the long-side direction of the filler-containing film and a direction orthogonal to the long-side direction, and can be set according to an article to which the filler-containing film is pressure-bonded.

The distance between the fillers in the filler-containing film can be set according to an article to be connected and use applications. The number density of the fillers can be appropriately set usually within a range of 10 particles/mm² or more and 100,000 particles/mm² or less, and preferably 30 particles/mm² or more and 70,000 particles/mm² or less. For example, when the filler-containing film is used as an anisotropic conductive film, the distance between the conductive particles that are the fillers 2 can be appropriately set according to the size, shape, and terminal pitch of terminals to be connected using the anisotropic conductive film. When the filler-containing film is used as an anisotropic conductive film, the number density of the conductive particles may be 30 particles/mm² or more, and preferably 150 to 70,000 particles/mm². In a case of a fine pitch application, the number density is preferably 6,000 to 42,000 particles/mm², more preferably 10,000 to 40,000 particles/mm², and further preferably 15,000 to 35,000 particles/mm². When the particle diameter of the conductive particles is 10 μm or more, the number density of the conductive particles is preferably 30 to 6,000 particles/mm².

In terms of exerting effects of the fillers contained, the area occupancy ratio of the fillers that is calculated by the following expression involving the number density of the fillers is preferably 0.3% or more. In terms of suppressing the thrust force required for a pressing jig to pressure-bond the filler-containing film to an article, the area occupancy ratio of the fillers is preferably 35% or less, and more preferably 30% or less.

Area occupancy ratio of fillers (%)=[number density of fillers as viewed in plan view]×[average area per filler as viewed in plan view]×100

The number density of the fillers is determined by observation with a metallographical microscope. Additionally, the number density of the fillers may be determined by measurement in an observed image with an image analysis software (for example, WinROOF (available from Mitani Corporation) or A-zou kun (registered trademark) (available from Asahi Kasei Engineering Corporation). An observation method and a measurement method are not limited to the aforementioned methods.

In the cross-sectional view (FIG. 1B) in which the filler-containing film is cut in a film thickness direction, it is preferable that apexes of the fillers in the film thickness direction be aligned to be flush with a surface of the insulating resin layer 10 or a surface parallel to the surface. This facilitates even pressure bonding of the filler-containing film to an article.

### <Fine Solid>

In order to impart a function different from that of the fillers 2 to the filler-containing film 1A, the insulating resin layer 10 may contain various fine solids 3 made of a material different from that of the fillers 2. For example, when the fillers 2 are the conductive particles, the insulating resin layer 10 may contain, as the fine solid 3, a viscosity modifier, a thixotropic agent, a polymerization initiator, a coupling agent, a flame retardant, or the like. More specifically, examples of the viscosity modifier may include silica powder and alumina powder.

In terms of the distinction between the fillers 2 and the fine solid 3, suppose a case where conductive particles are used as the fillers 2 and the filler-containing film is used as an anisotropic conductive film. In this case, when the fine solid is kneaded in the insulating resin layer as described in Patent Literature 5 and the conductive particles are pushed into the insulating resin layer to hold the conductive particles in the insulating resin layer, the conductive particles and the fine solid can be easily distinguished from each other by the respective distribution states in the insulating resin layer.

The particle diameter of the fine solid 3 is preferably smaller than the particle diameter of the filler 2. When the filler-containing film is used as an anisotropic conductive film, the fine solid to be contained as a viscosity modifier can have an average particle diameter of preferably less than 1 μm, more preferably 5 nm to 0.3 μm, or preferably ⅓ to ½ of the average particle diameter of the conductive particles to be contained as the filler.

In terms of the content of the fine solid 3 in the insulating resin layer 10, when an anisotropic conductive film is produced by, as described in the aforementioned Patent Literature 5, kneading the fine solid in the insulating resin layer and pushing the conductive particles into the insulating resin layer, there is no particular limitation unless the pushing of the conductive particles is inhibited. From the viewpoint of ensuring the precision of the disposition of the conductive particles, the content of the fine solid is preferably 3% by mass or more, and more preferably 5% by mass or more. As it is more necessary to perform pushing in two stages in the anisotropic conductive connection, the fine solid 3 can be contained in the insulating resin layer 10 in a high concentration. On the other hand, from the viewpoint of ensuring fluidity required for the film for connection of the electronic components, the content of the fine solid 3 is preferably 50% by mass or less, more preferably 40% by mass or less, and still more preferably 35% by mass or less, relative to the insulating resin layer 10.

### <Insulating Resin Layer>

In the present invention, the insulating resin layer may be composed of a single insulating resin layer or a layered body of a plurality of insulating resin layers. The insulating resin layer 10 of the filler-containing film 1A shown in FIG. 1A and FIG. 1B is formed by laminating insulating resin layers 11 and 12 with their dried surfaces facing inward and the surfaces on the release substrate side facing outward, where the insulating resin layers 11 and 12 are formed by applying the same insulating resin layer-forming composition to a smooth release substrate and drying the composition by a producing method of a filler-containing film to be described later. In the filler-containing film 1A, the interface between these two insulating resin layers 11 and 12 can be observed. The surface on which the insulating resin layer-forming composition has been applied and dried tends to be roughened due to the fine solid contained in the composition. When the surfaces of the insulating resin layers 11 and 12 on which the composition has been applied and dried are faced inward and superposed on each other as shown in FIG. 1B, the surface of the filler-containing film becomes a surface to which the smooth surface of the release substrate is transferred. Thus, it is considered that it becomes easy to uniformly thermocompression-bond the filler-containing film to an article.

### <Resin Composition for Forming Insulating Resin Layer>

The resin composition for forming the insulating resin layer 10 is appropriately selected depending on the use application of the filler-containing film, and can be formed from a thermoplastic resin composition, a high viscosity adhesive resin composition, or a curable resin composition. For example, when the filler-containing film is used as an anisotropic conductive film, a curable resin composition formed from a polymerizable compound and a polymerization initiator can be used similarly to a resin composition for forming an insulating resin layer of an anisotropic conductive film described in Patent Literature 5. In this case, a thermal polymerization initiator may be used as the polymerization initiator, and a photopolymerization initiator may be used. These initiators may be used in combination. For example, a cationic polymerization initiator is used as a thermal polymerization initiator, an epoxy resin is used as a thermo-polymerizable compound, a photoradical polymerization initiator is used as a photopolymerization initiator, and an acrylate compound is used as a photopolymerizable compound. As a thermal polymerization initiator, a thermal anionic polymerization initiator may be used. As the thermal anionic polymerization initiator, a microcapsule type latent curing agent comprising an imidazole modified body as a nucleus and a surface thereof coated with polyurethane is preferably used.

### <Lowest Melt Viscosity of Insulating Resin Layer>

The lowest melt viscosity of the insulating resin layer 10 is not particularly limited as long as the fillers are pushed into the insulating resin layer. In order to suppress an unnecessary flow of the fillers 2 when the filler-containing film 1A is thermocompression-bonded to an article, the lowest melt viscosity of the insulating resin layer is preferably 1,500 Pa·s or more, more preferably 2,000 Pa·s or more, further preferably 3,000 to 15,000 Pa·s, and particularly preferably 3,000 to 10,000 Pa·s. The lowest melt viscosity can be determined, for example, with a rotary rheometer (manufactured by TA Instruments) using a measurement plate having a diameter of 8 mm with a measurement pressure of 5 g constantly held. More specifically, the lowest melt viscosity can be determined by setting the temperature increasing rate to 10° C./min, the measurement frequency to 10 Hz, and the load variation with respect to the measurement plate to 5 g at a temperature range of 30 to 200° C. The lowest melt viscosity can be adjusted by changing the kind and amount of the fine solid contained as a melt viscosity modifier, and an adjustment condition of the resin composition.

### <Thickness of Insulating Resin Layer>

As described above, the insulating resin layer in the filler-containing film may be composed of a single insulating resin layer or a layered body of a plurality of insulating resin layers. In both the cases, the thickness of the insulating resin layer is preferably 0.3 or more times, more preferably 0.6 or more times, further preferably 0.8 or more times, and particularly preferably 1 or more times the particle diameter of the fillers 2 in order to stably push the fillers into the insulating resin layer in a production process of the filler-containing film. The upper limit of the thickness of the insulating resin layer is not particularly limited, and the thickness of the insulating resin layer may be appropriately adjusted according to an article to which the filler-containing film is thermocompression-bonded. When the thickness of the insulating resin layer is too large, the fillers 2 are likely to be unnecessarily affected by the flow of the resin during thermocompression bonding of the filler-containing film to an article, and the absolute amount of the fine solid contained in the insulating resin layer is increased. Thus, thermocompression bonding to an article may be impaired. Accordingly, the thickness of the insulating resin layer is preferably 20 or less times, and more preferably 15 or less times the particle diameter of the fillers 2.

On the other hand, when the filler-containing film is a layered body of the insulating resin layer containing the fillers embedded and a low-viscosity resin layer, the thickness of the low-viscosity resin layer may be appropriately adjusted according to the use application of the filler-containing film, as described below. When the thickness of the low-viscosity resin layer is too small, the variation of the thickness is relatively increased. Therefore, the thickness of the low-viscosity resin layer is preferably 0.2 or more times, and more preferably 1 or more times the particle diameter of the fillers 2. When the thickness of the low-viscosity resin layer is too large, it is increasingly difficult to layer the low-viscosity resin layer and the insulating resin layer. Therefore, the thickness of the low-viscosity resin layer is preferably 50 or less times, more preferably 15 or less times, and further preferably 8 or less times the particle diameter of the fillers 2.

When the filler-containing film is the layered body of the insulating resin layer containing the fillers embedded and the low-viscosity resin layer, it is preferable that the total thickness of the resin layers in the filler-containing film be smaller in terms of suppressing an unnecessary flow of the fillers 2 during thermocompression bonding of the filler-containing film to an article, suppressing protrusion of the resin and blocking in a wound body of the filler-containing film, and increasing the film length per unit weight of the filler-containing film. However, when the total thickness of the resin layers is too small, the handleability of the filler-containing film is deteriorated. Further, bonding of the filler-containing film to an article may be difficult. Therefore, an adhesive force required for temporary pressure bonding during thermocompression bonding of the filler-containing film to an article may not be obtained, and an adhesion required for final pressure bonding may not be obtained due to a lack of the amount of the resin. Accordingly, the total thickness of the resin layers in the filler-containing film is preferably 0.6 or more times, more preferably 0.8 or more times, further preferably 1 or more times, and particularly preferably 1.2 or more times the particle diameter of the fillers 2.

On the other hand, the upper limit of the total thickness of the resin layers including the insulating resin layer and the low-viscosity resin layer is not particularly limited and may be appropriately adjusted according to an article to which the filler-containing film is thermocompression-bonded. When the total thickness of the resin layers is too large, the fillers 2 are likely to be unnecessarily affected by the flow of the resin during thermocompression bonding of the filler-containing film to an article, and the absolute amount of the fine solid contained in the resin layers is increased. Thus, thermocompression bonding to an article may be impaired. Accordingly, the total thickness of the resin layers is preferably 50 or less times, more preferably 15 or less times, and further preferably 8 or less times the particle diameter of the fillers 2. When the total thickness is 4 or less times, and preferably 3 or less times, an influence of the resin flow on the filler disposition is considered to be minimal.

When the filler-containing film is configured as an anisotropic conductive film, the conductive particles may be embedded in or exposed from the insulating resin layer. When the filler-containing film is configured as an anisotropic conductive film and the insulating resin layer and the low-viscosity resin layer are provided as resin layers, the total thickness of the resin layers can fall within the aforementioned range. However, in terms of dealing with a decrease in the height of a bump in an electronic component to be connected, it is preferable that the total thickness of the resin layers be smaller than the aforementioned range. When the resin layers are made thin, connection of the conductive particles to the bump is facilitated. Therefore, the lower limit of the total thickness of the resin layers is preferably 0.6 or more times, more preferably 0.8 or more times, and further preferably 1 or more times the particle diameter of the conductive particles. When the total thickness thereof is too large, a thrust force required for pushing is too high. The upper limit thereof is thus 4 or less times, preferably 3 or less times, more preferably 2 or less times, further preferably 1.8 or less times, and particularly preferably 1.5 or less times the particle diameter of the conductive particles. The ratio of the thickness of the insulating resin layer to that of the low-viscosity resin layer may be appropriately adjusted according to a relationship between the particle diameter of the conductive particles and the bump height and a required adhesion, and the like.

### <Adhesive Force of Insulating Resin Layer>

It is preferable that the insulating resin layer have an adhesive force capable of temporary pressure bonding to an article to which the filler-containing film is thermocompression-bonded before thermocompression bonding. The adhesive force of the filler-containing film can be measured in accordance with JIS Z 0237 and measured as a tack force by a probe method in accordance with JIS Z 3284-3 or ASTM D 2979-01. For example, the tack force of each of the front and rear surfaces of the filler-containing film by a probe method is measured at a probe-pressing rate of 30 mm/min, an applied pressure of 196.25 gf, a pressing time of 1.0 sec, a peeling rate of 120 mm/min, and a measurement temperature of 23° C.±5° C. Even when the filler-containing film includes the insulating resin layer and the low-viscosity resin layer as resin layers or includes only the insulating resin layer, the tack force of at least one of the front and rear surfaces may be 1.0 kPa (0.1 N/cm²) or more, preferably 1.5 kPa (0.15 N/cm²) or more, and further preferably more than 3 kPa (0.3 N/cm²). In this case, one of the surfaces of the filler-containing film is bonded to a plate glass, and the tack force of the other may be measured. One of the surfaces of the filler-containing film may be bonded to a flexible thermoplastic resin film (for example, a PET film, a silicone rubber or the like that is not subjected to a mold release treatment with a thickness of 20 or less), but not a plate glass. When a bonded surface of the filler-containing film is inversed, the tack forces of the front and rear surfaces of the filler-containing film can be measured under the same condition.

In particular, when the filler-containing film includes a release substrate on both the front and rear surfaces, it is preferable that the front and rear surfaces of the filler-containing film be used so that the surface that has been bonded to an electronic component and the surface on an opposite side exert the aforementioned tack forces. When the filler-containing film includes a release substrate on one of the surfaces like a wound body of the filler-containing film, it is preferable that the surface on a side of the release substrate exert the aforementioned tack force. When the filler-containing film includes the insulating resin layer and the low-viscosity resin layer, it is preferable that the surface of the low-viscosity resin layer have the aforementioned tack force. On the other hand, the surface that has been bonded to an electronic component when the filler-containing film includes the release substrate on both the front and rear surfaces, the surface on which the release substrate is not provided when the filler-containing film includes the release substrate on one of the surfaces, and the surface on a side of the insulating resin layer when the filler-containing film includes the insulating resin layer and the low-viscosity resin layer may not necessarily have the aforementioned tack force, but desirably has the tack force. Preferable tack forces of both the front and rear surfaces of the filler-containing film are different. This is because when the filler-containing film is configured as an anisotropic conductive film, a surface of the anisotropic conductive film on a side opposite to the release substrate is generally bonded to a second electronic component such as a substrate during use, the release substrate is then peeled, and a first electronic component is mounted on a surface from which the release substrate has been peeled (i.e., a surface on a side of the release substrate). At that time, an adhesive performance capable of precisely fixing a mounted component needs to be secured.

When the mounted component is small, slight shifting cannot be permitted during mounting. However, it is assumed that an adhesive force required for mounting can be permitted even when the adhesive force is decreased relative to a larger mounted component. Therefore, the required adhesive force may be set according to the mounted component.

The adhesive force of the filler-containing film can be determined in accordance with an adhesion strength test described in Japanese Patent Application Laid-Open No. 2017-48358. In this adhesion strength test, for example, the filler-containing film is held between two glass plates, one of the glass plates is fixed, and the other is peeled at a peeling rate of 10 mm/min and a test temperature of 50° C. At that time, the adhesion state of the fixed glass plate and the filler-containing film is enhanced. Thus, the adhesive force between the glass plate peeled and a surface of the filler-containing film that is bonded to the glass plate can be measured. The thus measured adhesive force is preferably 1 N/cm² (10 kPa) or more, and more preferably 10 N/cm² (100 kPa) or more.

In addition, the adhesive force of the filler-containing film can be determined in a test in which one end of a specimen is bonded while being aligned with the other, and the other end is pulled up to peel the specimen. The adhesive force determined by this test procedure may be equal to the result of the aforementioned adhesion strength test (1 N/cm² (10 kPa) or more). When the adhesive force determined in the aforementioned adhesion strength test is sufficiently high (for example, 10 N/cm² (100 kPa) or more), the adhesive force by this test procedure may be 10% or more of the adhesive force in the adhesion strength test.

Even when an article to which the film is thermocompression-bonded is, for example, an electronic component of which the maximum dimension is less than 0.8 mm, which is smaller than a general IC chip, a problem about shifting in temporary pressure bonding is eliminated due to the aforementioned adhesive force of the filler-containing film. Even when the article is an electronic component of which the maximum dimension is about 450 cm, which is the same as a large TV, bonding can be stabilized due to the aforementioned adhesive force of the filler-containing film.

Such adhesiveness can be imparted to the insulating resin layer by appropriately adjusting a resin composition constituting the insulating resin layer or improving the smoothness of the insulating resin layer that forms an outer surface of the filler-containing film by a producing method of the filler-containing film described below.

### <Producing Method of Filler-Containing Film 1A>

The filler-containing film 1A can be produced as follows.

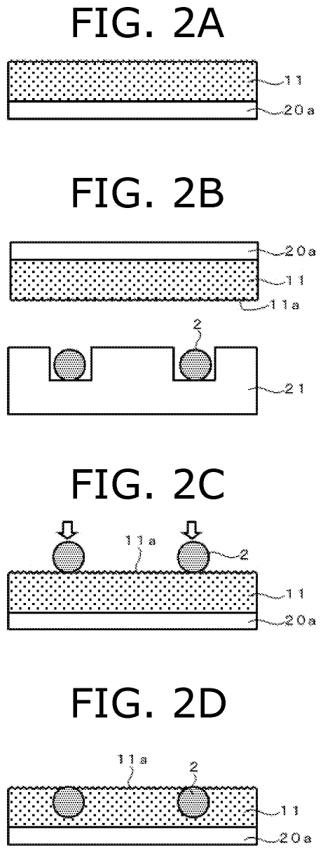

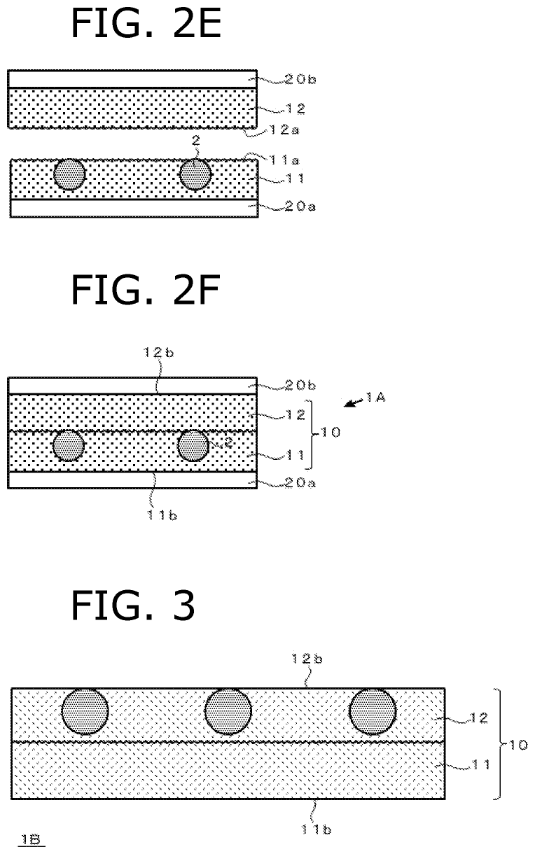

A step of applying the aforementioned insulating resin layer-forming composition containing the fine solid to a release substrate 20a having a smooth surface, such as a PET film, and drying the insulating resin layer-forming composition to form an insulating resin layer 11 (FIG. 2A) is performed.

Like a producing method of an anisotropic conductive film described in Patent Literature 5, steps of filling, with the fillers 2, concaves of a mold 21 having the concaves that correspond to a regular disposition of the fillers 2 (FIG. 2B), transferring the fillers 2 to a dried surface (a surface on a side opposite to the release substrate 20a) 11a of the insulating resin layer 11 (FIG. 2C), and pushing the fillers 2 into the insulating resin layer 11 (FIG. 2D) are then performed.

On the other hand, an insulating resin layer 12 is formed on a release substrate 20b similarly to the insulating resin layer 11. Steps of facing the insulating resin layer 12 and the insulating resin layer 11 containing the pushed fillers with the release substrates 20a and 20b facing outward (FIG. 2E) and layering the insulating resin layers (FIG. 2F) are performed. Thus, the filler-containing film 1A can be obtained (FIG. 1A).

<Smoothness of Surface of Filler-Containing Film and Proportion of Repeat Pitch of Fillers after Thermocompression Bonding to that Before Thermocompression Bonding>

Surfaces of the filler-containing film 1A produced as described above are surfaces 11b and 12b of the insulating resin layers on the release substrates 20a and 20b sides. Therefore, the surfaces 11b and 12b become smooth since the smoothness of the surfaces of the release substrates 20a and 20b are transferred thereto. When the filler-containing film 1A is thermocompression-bonded to an article, the adhesiveness of the insulating resin layers 11 and 12 to an article can be improved, and the filler-containing film can be evenly pressed. Thus, an uneven flow of the fillers 2 caused by thermocompression bonding is suppressed, and the disposition of the fillers 2 after thermocompression bonding is a disposition in which the original regular disposition is evenly extended. When the filler-containing film 1A is held between smooth surfaces and thermocompression bonding is performed at an area under a predetermined heating and pressurization condition according to the compositions of the insulating resin layers, the proportion of the repeat pitch of the fillers after thermocompression bonding to that before thermocompression bonding thus falls within 300% or less, which is significantly smaller than that when the dried surfaces 11a and 12a of the insulating resin layers form the surfaces of the filler-containing film.

A thermocompression bonding condition where the proportion of the repeat pitch of the fillers is 300% or less can be easily found since temperature, pressure, and time can be appropriately selected from usual heating and pressurization conditions of the insulating resin layers.

In investigation of the proportion of the repeat pitch of the fillers after thermocompression bonding to that before thermocompression bonding, a glass plate, or the like, can be used as the smooth surfaces between which the filler-containing film is held. A smooth surface of an article to which the filler-containing film is thermocompression-bonded may be used. For example, when the filler-containing film is configured as an anisotropic conductive film, a smooth surface of an electrode, a bump, or the like, which is to be connected can be used. Thus, the proportion of the repeat pitch of the conductive particles after thermocompression bonding to that before thermocompression bonding in an electronic component to be connected can be evaluated.

In investigation of the proportion of the repeat pitch of the fillers after thermocompression bonding to that before thermocompression bonding, the area of the smooth surface may be an area where the arrangement of the fillers can be confirmed. When the fillers are disposed in a lattice form or in a group of a specific shape, the area may be an area where at least a unit lattice or repeat unit of the specific shape exists. When the fillers are disposed in a lattice form, the area is preferably an area where preferably 3 or more, more preferably 5 or more, and further preferably 10 or more unit lattices exist in an arrangement axis in which the pitch between the fillers is the smallest. The distance between repeat units existing at centers thereof (for example, in a hexagonal lattice arrangement, a distance between centers of particles) is measured as a repeat pitch. Also in a case of the repeat unit of the specific shape, the repeat pitch can be determined similarly. On the other hand, when the thermocompression bonding area is excessively increased, it takes an unreasonably long time to measure the repeat pitch. The area is thus an area where preferably 1,000 or less fillers, more preferably 500 or less fillers, further preferably 200 or less fillers, and particularly preferably 50 or less fillers are contained.

In order to secure such an area as a smooth surface, the filler-containing film is configured as an anisotropic conductive film, and the proportion of the repeat pitch of the conductive particles after thermocompression bonding to that before thermocompression bonding is evaluated. In this case, as the smooth surface, for example, an input terminal, of which the area is relatively large, of an electronic component for COG connection can be used. When an electronic component to be connected does not have a terminal with such an area, an electronic component having a terminal with such an area may be used for evaluation. As an example, a smooth surface of a terminal in which the smallest side is 30 μm or more, and preferably 40 μm or more is used.

The number of measurements (N number) of the repeat pitch is preferably 50 or more, and more preferably 100 or more. Such an N number is difficult depending on the number density of the fillers, and therefore the N number may be less than the aforementioned numbers.

The measurement direction of the repeat pitch is preferably a direction in which the proportion of the repeat pitch after thermocompression bonding to that before thermocompression bonding is increased. Even when the proportion of the repeat pitch after thermocompression bonding to that before thermocompression bonding is varied according to the measurement direction, an actual proportion of the repeat pitch can be equal to or less than a measured proportion of the repeat pitch, and the precision of a filler disposition can be confirmed. On the other hand, when the repeat pitch is measured at a plurality of regions, a portion to be measured may be selected at each of the regions, and the repeat pitch may be determined. For example, repeat pitches of which the number is 10% of a predetermined N number are measured at a region, and repeat pitches of which the number is 10% of the predetermined N number are similarly measured at 9 other regions, and these repeat pitches are averaged. The N number and the number of regions where N repeat pitches are measured can be appropriately adjusted according to an article to which the filler-containing film is thermocompression-bonded.

In investigation of the proportion of the repeat pitch of the conductive particles after thermocompression bonding to that before thermocompression bonding using a smooth surface of an electronic component, the movement of the conductive particles when a direction of the resin flow is a terminal arrangement direction may be different from that when the direction of the resin flow is a direction orthogonal to the terminal arrangement direction. In this case, it is preferable that the pitch be measured in a direction in which the movement of the conductive particles is large.

When terminals of different sizes are provided on the smooth surface of the electronic component, it is preferable that a portion where the terminal size and the distance between the terminals are large, and a difference between the movement of the conductive particles in the terminal arrangement direction and that in the direction orthogonal to the terminal arrangement direction is small be selected, and the pitch be measured at the portion. For example, in a case of COG connection, the terminal size and the distance between terminals of an input terminal and an output terminal are different. In this case, at the input terminal in which the terminal size and the distance between terminals are large, the pitch is measured. Thus, the movement of the conductive particles and disorder of the arrangement are easily evaluated.

The measurement direction and measurement portion of the pitch for investigation of the proportion of the repeat pitch of the fillers after thermocompression bonding to that before thermocompression bonding can be the same as described above even when the filler-containing film is a film other than the anisotropic conductive film. When, in investigation of the proportion of the repeat pitch of the fillers after thermocompression bonding to that before thermocompression bonding using an article to be connected, the article has no smooth surface, smooth glass plates can be used instead. In this case, it is preferable that a thermocompression bonding condition be adjusted so as to be equal to the thermocompression bonding condition (reaching temperature, pressure, pressure bonding time, and the like, which are required for the filler-containing film) of the article to be connected.

Examples of a measurement procedure of the pitch may include known image observation devices such as an optical microscope, a metallographical microscope, and an electron microscope, and measurement systems such as WinROOF and A-zou kun (registered trademark). They may be appropriately combined.

According to the filler-containing film of the present invention, the smoothness of the surface is improved, and the adhesiveness to an article is improved. Therefore, the proportion of the repeat pitch of the fillers after thermocompression bonding to that before thermocompression bonding can be decreased to 300% or less, as described above. When the filler-containing film 1A is configured as an anisotropic conductive film, temporary pressure bonding properties of the anisotropic conductive film to an electronic component are improved, and in final pressure bonding the conductive particles capturing properties at terminals of the electronic component are improved, and short circuit is suppressed. Accordingly, even when the terminal size of the electronic component is decreased, conduction can be reliably achieved, and short circuit can be suppressed. Due to improved adhesiveness, mounting of an electronic component to be connected, which is either a large electronic component or a small electronic component, is stabilized, and production of a connection body is facilitated. Thus, the productivity can be improved. Especially, in an electronic component in which the width of terminals is decreased, the necessity for precise alignment is increased. Therefore, large effects are obtained by the filler-containing film of the present invention.

### <Filler-Containing Film 1B>

The filler-containing film of the present invention can have various aspects. For example, a filler-containing film 1B illustrated in FIG. 3 is different from the filler-containing film 1A in that positions of the fillers 2 on a film surface side are aligned in a film thickness direction to be flush with a surface of the filler-containing film 1B (the surface 12b of the insulating resin layer 12 on the release substrate side).

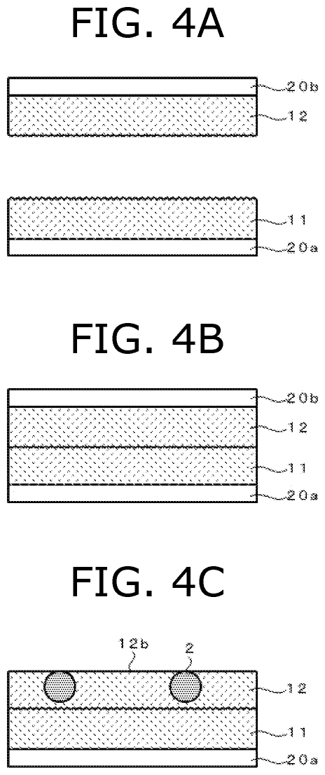

The filler-containing film 1B can be produced by steps of forming the insulating resin layers 11 and 12 on the release substrates 20a and 20b, respectively, in the same manner as that in the producing method of the filler-containing film 1A (FIG. 4A), layering the insulating resin layers 11 and 12 with the release substrates 20a and 20b facing outward to form a layered body of the insulating resin layers (FIG. 4B), and peeling the release substrate 20b and pushing the fillers 2 from the surface 12b of the insulating resin layer 12 after peeling (FIG. 4C).

The surfaces 11b and 12b of the insulating resin layers that form surfaces of the filler-containing film 1B are smooth since the smoothness of the surfaces of the release substrates 20a and 20b are transferred thereto. The filler-containing film 1B also exerts the same effects as those of the filler-containing film 1A.

### <Filler-Containing Film 1C>

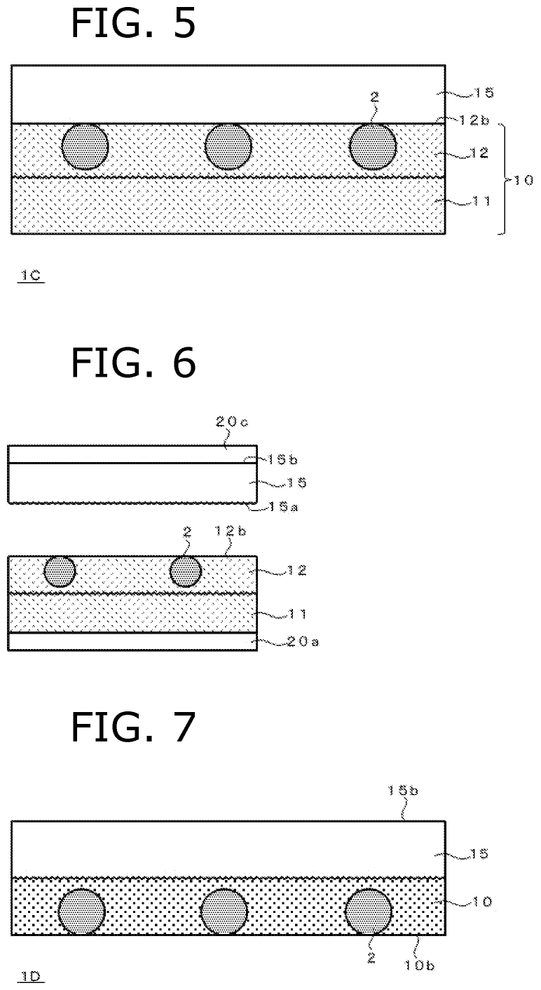

In a filler-containing film 1C illustrated in FIG. 5, a low-viscosity resin layer 15 is layered on a surface of the aforementioned filler-containing film 1B into which the fillers are pushed (the surface 12b of the insulating resin layer on the release substrate side) (FIG. 4C).

The low-viscosity resin layer 15 is a resin layer of which the lowest melt viscosity at a range of 30 to 200° C. is lower than that of the insulating resin layer 10. When two articles facing through the filler-containing film 1C are thermocompression-bonded by layering the low-viscosity resin layer 15 on the insulating resin layer 10, the adhesion properties thereof can be improved. In particular, when electronic components are anisotropically, conductively connected to each other using the fillers 2 as conductive particles and the filler-containing film 1C as an anisotropic conductive film, a space formed by electrodes or bumps of the electronic components is filled with the low-viscosity resin layer 15. Thus, the adhesion properties between the electronic components can be improved.

As the difference between the lowest melt viscosity of the insulating resin layer 10 and that of the low-viscosity resin layer 15 is larger, a space between two articles connected through the filler-containing film 1C is more easily filled with the low-viscosity resin layer 15. Therefore, when the fillers 2 are used as conductive particles and the filler-containing film 1C is used as an anisotropic conductive film, a space formed by electrodes or bumps of the electronic components is easily filled with the low-viscosity resin layer 15. Thus, the adhesion properties between the electronic components are likely to be improved. As the difference is larger, the movement of the insulating resin layer 10 holding the fillers 2 with respect to that of the low-viscosity resin layer 15 during thermocompression bonding is relatively small. Thus, the conductive particles capturing properties at terminals are likely to be improved.

The ratio (A1/A2) of the lowest melt viscosity A1 of the insulating resin layer 10 to the lowest melt viscosity A2 of the low-viscosity resin layer 15 depends on the ratio of the thickness of the insulating resin layer 10 to that of the low-viscosity resin layer 15 in practical terms and is preferably 2 or more, more preferably 5 or more, and further preferably 8 or more. On the other hand, when this ratio is too large, protrusion of a resin or blocking in a wound body of an elongated filler-containing film may be caused. Therefore, the ratio is preferably 30 or less, and more preferably 15 or less in practical terms. More specifically, the preferable lowest melt viscosity of the low-viscosity resin layer 15 satisfies the aforementioned ratio and is 3,000 Pa·s or less, more preferably 2,000 Pa·s or less, and particularly preferably 100 to 2,000 Pa·s.

The low-viscosity resin layer 15 can be formed from the same resin composition as that for the insulating resin layer 10 by adjusting the viscosity thereof. If necessary, the low-viscosity resin layer 15 may contain the fine solid.

As a method for layering the low-viscosity resin layer 15 on the insulating resin layer 10 containing the fillers 2 having been pushed, a low-viscosity resin layer-forming composition is applied to a release substrate 20c such as a release film and dried to form the low-viscosity resin layer 15, a dried surface 15a is faced to a surface of the insulating resin layer 10 into which the fillers 2 have been pushed, so that the low-viscosity resin layer 15 is layered on the insulating resin layer 10, as illustrated in FIG. 6. When the content of the fine solid in the low-viscosity resin layer 15 is low and there is no substantial difference between the adhesiveness of the dried surface 15a of the low-viscosity resin layer 15 and that of a surface 15b on a side opposite to the dried surface 15a, the low-viscosity resin layer-forming composition may be applied directly to the surface of the insulating resin layer 10 into which the fillers 2 have been pushed to form the low-viscosity resin layer 15.

### <Filler-Containing Film 1D>

In a filler-containing film 1D illustrated in FIG. 7, apexes of the fillers 2 are aligned and disposed to be flush with an outer surface of the insulating resin layer 10 of a layered body in which a dried surface of the insulating resin layer 10 faces a dried surface of the low-viscosity resin layer 15. The filler-containing film 1D can be produced by the following steps.

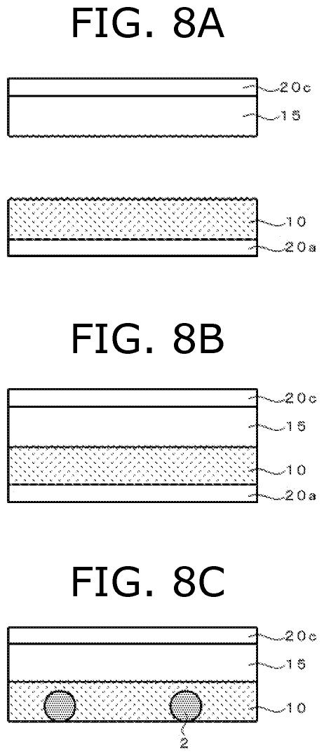

A step of applying the insulating resin layer-forming composition containing the fine solid to the release substrate 20a, and drying the composition to form the insulating resin layer 10 is performed, and a step of applying the low-viscosity resin layer-forming composition to the release substrate 20c and drying the composition to form the low-viscosity resin layer 15 is also performed (FIG. 8A). Next, a step of layering the insulating resin layer 10 and the low-viscosity resin layer 15 with the release substrates 20a and 20c thereof facing outward (i.e., with the dried surfaces facing to each other) to form the layered body of the insulating resin layer 10 and the low-viscosity resin layer 15 is performed (FIG. 8B). A step of peeling the release substrate 20a of the insulating resin layer 10 and pushing the fillers 2 from a surface of the insulating resin layer where the release substrate has been peeled is performed (FIG. 8C).

The surface 10b of the insulating resin layer and the surface 15b of the low-viscosity resin layer 15 that form surfaces of the thus obtained filler-containing film 1D are smooth since the smoothness of the surfaces of the release substrates 20a and 20c are transferred. The filler-containing film 1D also exerts the same effects of the filler-containing film 1A.

### <Filler-Containing Film 1E>

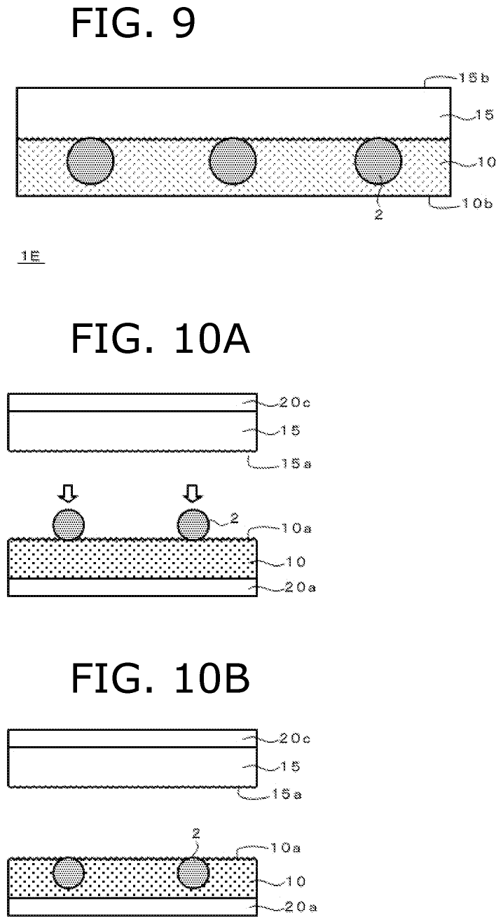

In a filler-containing film 1E illustrated in FIG. 9, apexes of the fillers 2 are aligned and disposed to be flush with a dried surface of the insulating resin layer 10 of the layered body in which the dried surface of the insulating resin layer 10 faces the dried surface of the low-viscosity resin layer 15. The filler-containing film 1E can be produced by the following steps.

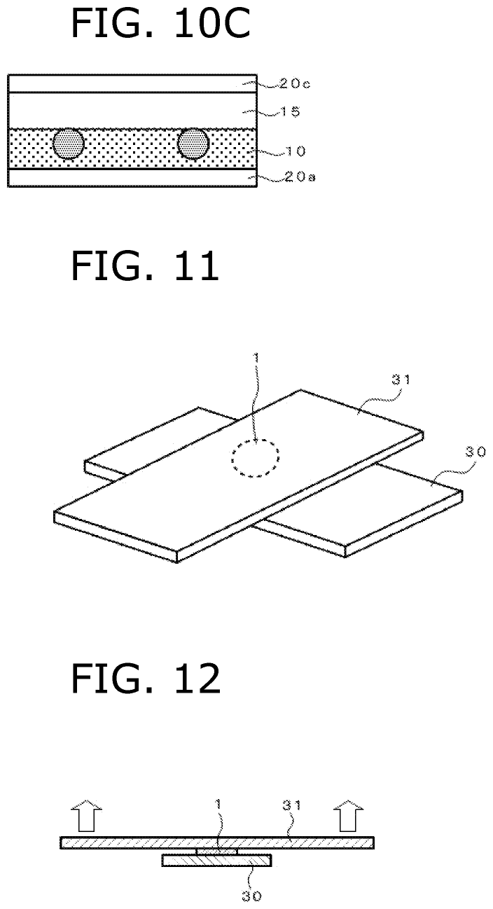

Specifically, similarly to the case where the filler-containing film 1D is produced, a step of applying the insulating resin layer-forming composition containing the fine solid to the release substrate 20a, and drying the composition to form the insulating resin layer 10 is performed, and a step of applying the low-viscosity resin layer-forming composition to the release substrate 20c, and drying the composition to form the low-viscosity resin layer 15 is also performed (FIG. 8A). Next, a step of pushing the fillers 2 from a surface (a dried surface 10a) of the insulating resin layer 10 on a side opposite to the release substrate 20a is performed (FIG. 10A). Thus, apexes of the fillers 2 in the film thickness direction are aligned to be flush with the dried surface 10a of the insulating resin layer 10 (FIG. 10B). The dried surface 10a and the dried surface 15a of the aforementioned low-viscosity resin layer are faced to each other, so that the insulating resin layer and the low-viscosity resin layer are layered (FIG. 10C).

The surface 10b of the insulating resin layer and the surface 15b of the low-viscosity resin layer 15 that form surfaces of the thus obtained filler-containing film 1E are smooth since the smoothness of the surfaces of the release substrates 20a and 20c are transferred. Thus, the filler-containing film 1E also exerts the same effects of the filler-containing film 1A.

### <Wound Body of Filler-Containing Film>

As a product form of the filler-containing film, a wound body can be formed. The length of the wound body is not particularly limited and is preferably 5,000 m or less, more preferably 1,000 m or less, and further preferably 500 m or less in terms of handleability of a shipping material. In terms of mass productivity of the wound body, the length thereof is preferably 5 m or more.

The wound body may be obtained by joining the filler-containing films that are shorter than the full length of the wound body. The wound body may have a plurality of joined portions regularly or randomly.

The film width of the wound body is not particularly limited. In terms of the lower limit of a slit width when a wide filler-containing film is slit and the wound body is produced, the film width thereof is preferably 0.3 mm or more. In terms of stabilizing the slit width, the film width thereof is more preferably 0.5 mm or more.

The upper limit of the film width is not particularly limited. From the viewpoint of carrying and handling properties, the upper limit thereof is preferably 700 mm or less, and more preferably 600 mm or less.

When the filler-containing film is used as an anisotropic conductive film, it is preferable that the film width be selected from 0.3 to 400 mm according to an article to be connected in terms of practical handleability. That is, when the anisotropic conductive film is used for an end of an electronic component to be connected, the film width is often equal to or less than about several millimeters. When the anisotropic conductive film is bonded to a relatively large electronic component (a substrate having an electrode wiring and a mounting portion on a surface, a wafer before cutting, etc.) as it is during use, a film width of about 400 mm may be required. In general, an anisotropic conductive film having a film width of 0.5 to 5 mm is often used.

### <Using Method of Filler-Containing Film>

The filler-containing film of the present invention can be used in bonding to an article like a conventional filler-containing film, and the article to be bonded is not particularly limited. Therefore, a variety of first components can be connected to a variety of second components through the filler-containing film, to obtain connection bodies of the first and second components. For example, when the filler-containing film is configured as an anisotropic conductive film, the anisotropic conductive film can be used in anisotropic conductive connection of a first electronic component such as a semiconductor element using PN junction (a power generation element such as a solar battery, an imaging element such as CCD, a light-emitting element, and a Peltier element), other various semiconductor elements, an IC chip, an IC module, or FPC to a second electronic component such as FPC, a glass substrate, a plastic substrate, a rigid substrate, or a ceramic substrate, and the filler-containing film can also be used for an electronic component in use applications other than anisotropic conductive connection. A surface of an article to which the filler-containing film is bonded may be smooth or have a step or a convex shape.

The shape, size, and use application of the first and second electronic components to be connected by the anisotropic conductive film are not particularly limited. The electronic components may be downsized and terminals may be narrowed, or high-precision alignment may be required for mounting of the electronic components. For examples, electronic components of which the bump area is extremely decreased to several tens of square micrometers to several thousands of square micrometers may be an object to be connected. On the other hand, the anisotropic conductive film can be used in mounting of electronic components that have a large external size. Mounted electronic components may be divided into a small piece during use. When the filler-containing film is used for a large TV, or the like, the filler-containing film may be bonded in a length of 1 m or more, for example, 4.5 m or more for each side. In this case, the filler-containing film may be used as a spacer film in which the fillers are used as spacers, in addition to the anisotropic conductive film.

An IC chip or a wafer may be stacked using the anisotropic conductive film of the present invention, to be multilayered. Electronic components to be connected by the anisotropic conductive film of the present invention are not limited to examples of the electronic components described above. The anisotropic conductive film can be used for various electronic components that have been diversified in recent years. The present invention includes a film-bonded body in which the filler-containing film of the present invention is particularly bonded to various articles, and particularly includes a connection body in which the first and second electronic components are connected to each other through the anisotropic conductive film.

A method for bonding the filler-containing film to an article may be pressure bonding, and preferably thermocompression bonding according to the use application of the filler-containing film. During bonding, light irradiation may be utilized.

The using method of the filler-containing film that is configured as the anisotropic conductive film is specifically as follows. For example, when the first electronic component is an IC chip and the second electronic component is a substrate; the first and second electronic components are generally mounted on a pressurization tool and a stage facing the first electronic component, respectively; the anisotropic conductive film is bonded to the second electronic component in advance; and the first and second electronic components are thermocompression-bonded using the pressurization tool. In this case, the anisotropic conductive film may be bonded to the first electronic component in advance, and the first electronic component is not limited to the IC chip.

When the first and second electronic components are connected to each other by thermocompression bonding, a resin around the conductive particles may be removed in advance before thermocompression bonding, if necessary, and temporary pressure bonding may be performed. Thus, an influence of a resin flow when the anisotropic conductive film is thermocompression-bonded to an electronic component can be decreased, and an unnecessary flow of the conductive particles can be suppressed. Specifically, in temporary pressure bonding, an electronic component to be connected is bonded to a surface of the anisotropic conductive film, and another electronic component is bonded to another surface of the anisotropic conductive film. At that time, the electronic component is pressed by a pressurization tool, so that a resin between the electronic components is partially removed. Then, thermocompression bonding is performed as final pressure bonding, so that the electronic components are connected (hereinafter, a connection method in which pressing is performed not only in thermocompression bonding during final pressure bonding but also temporary pressure bonding is referred to as connection by two-stage pushing). WO 2016/143789 describes that connection by two-stage pushing is performed using an anisotropic conductive film in which conductive particles are randomly dispersed. However, when connection by two-stage pushing is performed during connection of electronic components using the anisotropic conductive film in which conductive particles are regularly arranged like the present invention, an unnecessary flow of the conductive particles during thermocompression bonding can be largely decreased.

In connection of the first and second electronic components, the number of the first electronic component and the number of the second electronic component are not limited to one and one, respectively. For example, a plurality of first electronic components may be connected to a single second electronic component. The present invention also includes a producing method of a connection body in which the first and second electronic components are connected through the anisotropic conductive film.

### EXAMPLES

Hereinafter, the present invention will be more specifically described by Test Examples.

As a filler-containing film, anisotropic conductive films of Comparative Example 1 and Examples 1 to 4 were produced.

### Comparative Example 1

### (1) Formation of Insulating Resin Layer

An insulating resin layer-forming composition was prepared in a compounding ratio shown in Table 1, applied to a PET film, and dried to obtain an insulating resin layer (hereinafter referred to as high-viscosity resin layer) with a thickness shown in Table 2. The lowest melt viscosity (rotary rheometer (manufactured by TA instruments), measurement pressure: 5 g, temperature range: 30 to 200° C., temperature increasing rate: 10° C./min, measurement frequency: 10 Hz, measurement plate diameter: 8 mm, load variation with respect to the measurement plate: 5 g) of the high-viscosity resin layer was 9,000 Pa·s.

### (2) Pushing of Conductive Particles

As conductive particles, metal-coated resin particles (AUL703, available from Sekisui Chemical Co., Ltd., average particle diameter: 3 μm) described in Examples of Patent Literature 5 were used. By the method described in Examples of Patent Literature 5, the conductive particles were bonded to a dried surface of the high-viscosity resin layer of (1) and pressed (60° C., 0.5 Mpa) to be pushed into the dried surface of the high-viscosity resin layer (particle density: 28,000 particles/mm²). In this case, the conductive particles formed a hexagonal lattice arrangement, and apexes of the conductive particles in a film thickness direction were aligned to be flush with the dried surface of the high-viscosity resin layer.

### Example 1

A high-viscosity resin layer (thickness: 3 μm) was formed on a PET film in the same manner as that in Comparative Example 1.

On the other hand, a low-viscosity resin layer-forming composition was prepared in a compounding ratio shown in Table 1, applied to a PET film, and dried to form a low-viscosity resin layer with a thickness of 3 μm. The lowest melt viscosity (rotary rheometer (manufactured by TA instruments), measurement pressure: 5 g, temperature range: 30 to 200° C., temperature increasing rate: 10° C./min, measurement frequency: 10 Hz, measurement plate diameter: 8 mm, load variation with respect to the measurement plate: 5 g) of the low-viscosity resin layer was 300 Pa·s.

A dried surface of the high-viscosity resin layer on the PET film and a dried surface of the low-viscosity resin layer on the PET film were bonded to each other to form a layered body of the high-viscosity resin layer and the low-viscosity resin layer. The PET film on a side of the high-viscosity resin layer was peeled, and conductive particles were bonded to and pushed into a surface of the high-viscosity resin layer from which the PET film had been peeled, in the same manner as that in Comparative Example 1.

### Example 2

A high-viscosity resin layer was formed on a PET film in the same manner as that in Comparative Example 1. Conductive Particles were pushed into the resulting dried surface thereof.

On the other hand, a low-viscosity resin layer was formed on a PET film in the same manner as that in Example 1. The resulting dried surface thereof was bonded to the dried surface of the high-viscosity resin layer.

### Example 3

A high-viscosity resin layer (thickness: 3 μm) was formed on a PET film in the same manner as that in Comparative Example 1. Conductive Particles were pushed into the resulting dried surface thereof.

A high-viscosity resin layer (thickness: 3 μm) different from the high-viscosity resin layer was separately formed on a PET film, and dried surfaces of the high-viscosity resin layers were bonded to each other.

### Example 4

A high-viscosity resin layer (thickness: 3 μm) was formed on a PET film in the same manner as that in Comparative Example 1. A high-viscosity resin layer (thickness: 3 μm) that was the same as the aforementioned high-viscosity resin layer was separately formed, and dried surfaces thereof were bonded to each other to form a layered body of the two high-viscosity resin layers. One of the PET films of the layered body was peeled, and conductive particles were bonded to and pushed into the surface of the high-viscosity resin layer from which the PET film was peeled.

### Evaluation

The anisotropic conductive films of Examples and Comparative Example were subjected to the following evaluation tests (1) to (4). Results of (1) to (4) are shown in Table 2. In Comparative Example 1, the evaluation result of (2) adhesiveness of film surfaces (temporary pressure bonding test) was NG. Therefore, an anisotropic conductive film capable of normally producing a connection body for evaluation was selected as an evaluation object in (3) conduction resistance test and (4) conduction reliability test.

(1) Proportion (%) of Repeat Pitch of Particle Arrangement after Thermocompression Bonding to that Before Thermocompression Bonding

As electronic components for evaluation of the proportion of the repeat pitch of a particle arrangement after thermocompression bonding to that before thermocompression bonding, the following electronic components (a) and (b) were used. The anisotropic conductive film produced in each of Examples and Comparative Example was held between the electronic components (a) and (b), and thermocompression bonding was performed at a bump area (0.0024 mm²) containing at least 50 conductive particles or more at a temperature of 180° C. and a pressure of 60 Mpa for 5 seconds. In this case, a glass substrate of the electronic component (b) was disposed on a lower side of a film configuration shown in Table 2, and an IC for evaluation of the electronic component (a) was disposed on an upper side.

A repeat pitch P0 of conductive particles before thermocompression bonding and a repeat pitch P1 of the conductive particles after thermocompression bonding (a distance between centers of the conductive particles) (FIG. 1) were measured with respect to two axes for one bump at a central part of the bump area. That is, with respect to each of an axis (A axis) in which an angle with respect to a bump arrangement direction was the shallowest (close to parallel) and the movement of the resin was small and an axis (B axis) in which the angle with respect to the bump arrangement direction was the deepest and the movement of the resin was large, the pitch P0 before thermocompression bonding was measured. This measurement was performed at 20 bumps or more that stood in a line. The number of measurements with respect to each of the A axis and the B axis was 50. An average of the pitches P0 with respect to each axis was determined. The pitch P1 after thermocompression bonding was measured similarly. The number of measurements with respect to each of the A axis and the B axis was 50. The average of the pitches P1 with respect to each axis was determined. The proportion of the pitch after thermocompression bonding to that before thermocompression bonding ((P1/P0)×100%) with respect to each of the A axis and the B axis was determined.

### (a) Electronic Component for Evaluation:

### IC for Evaluation

External shape: 0.7×20.0 mm

Thickness: 0.2 mm

Au-plated bump: size: 40 μm×60 μm, distance between bumps: 20 μm, bump height: 5 μm

### (b) Electronic Component for Evaluation:

### Glass Substrate (ITO Wiring Glass Substrate)

Thickness: 0.3 mm

### (2) Adhesiveness of Film Surface

### (2-1) Temporary Pressure Bonding Test

A surface on a conductive particle-pushing side of the anisotropic conductive film produced in each of Examples and Comparative Example or a surface on a side opposite to the surface was bonded to a non-alkali glass for evaluation. Temporary pressure bonding was performed using a buffer material (polytetrafluoroethylene) with a thickness of 50 μm at a pressure bonding temperature of 70° C. and a pressure bonding pressure of 1 Mpa for a pressure bonding time of 1 second while the width of the anisotropic conductive film was 1.5 mm, and the length thereof was 50 mm. When the PET film on a side opposite to the bonded surface was peeled using tweezers, whether the anisotropic conductive film was peeled from the glass substrate with the PET or not was observed. This test was performed 100 times, and results were evaluated according to the following criteria.

### Evaluation Criteria

OK: in all the 100 tests, the anisotropic conductive film was not peeled from the glass substrate.

NG: in one or more of the 100 tests, the anisotropic conductive film was peeled from the glass substrate.

The anisotropic conductive films of Examples 1 and 2 were each disposed on a flat plane, and touch feeling with a finger was confirmed. At that time, the adhesive force on a side of the low-viscosity resin layer was larger than that on a side of the high-viscosity resin layer.

### (2-2) Adhesive Force Test 1

As illustrated in FIG. 11, two glass slides (26 mm×76 mm×1 mm) (Matsunami Glass Ind., Ltd.) 30 and 31 were superposed on each other while extending in different directions, and the anisotropic conductive film 1 produced in each of Examples was held between the glass slides in accordance with the adhesion strength test described in Japanese Patent Application Laid-Open No. 2017-48358. In this case, the anisotropic conductive films were each punched into a circular shape (diameter: 10 mm) and used. A surface of each of the anisotropic conductive films on a lower side of the “film configuration” shown in Table 2 was superposed on the glass slide 30 on a lower side. The glass slide 30 on the lower side was placed on a hot plate heated to 40 to 50° C. that was a general stage temperature for temporary bonding during mounting, pressed by fingers, heated for 30 seconds, and bonded to the surface of the anisotropic conductive film. Thus, the glass slide 30 on the lower side and the surface on the lower side of the anisotropic conductive film were in a temporary bonding state. Subsequently, the glass slide 31 on the upper side was disposed on and bonded to the surface on the upper side of the “film configuration” shown in Table 2. Thus, the glass slide 31 on the upper side was in a bonding state using an adhesive force of the surface on the upper side of the anisotropic conductive film.

With the anisotropic conductive film 1 held between the two glass slides 30 and 31 as described above, the glass slide 30 on the lower side was fixed by a jig in AGS-X series manufactured by Shimadzu Corporation, and both ends of the glass slide 31 on the upper side were pulled up by a jig in a vertical direction at a temperature of 50° C. and 10 mm/min, as illustrated in FIG. 12. At that time, a force when the glass slide 30 on the lower side was separated from the glass slide 31 on the upper side was measured. The value of the force was divided by the area of the anisotropic conductive film 1 to obtain a value of an adhesive force of the surface on the upper side of the “film configuration” in Table 2. In this case, an adhesion strength test was performed twice for each of Examples. The lowest value is shown in Table 2. In Examples 3 and 4, measurement was difficult, and therefore the variations of measured values were larger than those in Examples 1 and 2. In Comparative Example 1, the adhesive force based on touch feeling with a finger was smaller than those in Examples 3 and 4, and therefore the adhesion strength test was not performed.

### (2-3) Adhesive Force Test 2

The adhesive force (tack force) was measured as follows in an atmosphere of 22° C. by a tackiness tester (TACII, manufactured by RHESCA Co., LTD.). The anisotropic conductive film produced in each of Examples (1 cm×1 cm) was bonded to a plate glass (thickness: 0.3 mm). In this case, the surface on the lower side of the film configuration shown in Table 2 was bonded to the plate glass, and the surface on the upper side was used as a measurement surface for the tack force. The plate glass was placed on a silicone rubber stand of a sample stage. Subsequently, a columnar probe with a diameter of 5 mm (made of stainless and mirror-finished) of the tackiness tester was set above the measurement surface, brought into contact with the measurement surface at pressing rate of 30 mm/min, pressurized at a pressurization force of 196.25 gf for a pressurization time of 1.0 sec, and peeled off at a peeling rate of 120 mm/min by 2 mm from the measurement surface. At that time, the resistance of the probe received by the adhesive force of the measurement surface was measured as a load value. The maximum load when the probe was peeled off from the measurement surface was regarded as the adhesive force (tack force). The adhesive force was measured twice for each of Examples. The lowest value thereof is shown in Table 2. In Examples 3 and 4, measurement was difficult, and therefore the variations of measured values were larger than those in Examples 1 and 2. In Comparative Example 1, the adhesive force based on touch feeing with a finger was smaller than those in Examples 3 and 4, and therefore the measurement was not performed.

### (3) Conduction Resistance (Initial Conduction Resistance)

The anisotropic conductive film of each of Examples and Comparative Example was cut to have an area sufficient for connection, held between an IC for evaluation of conduction properties and a glass substrate, and pressurized under heating (180° C., 60 Mpa, 5 seconds) to obtain a connection body for each evaluation. The conduction resistance of the resulting connection body for evaluation was measured by a four-probe method and evaluated in accordance with the following criteria. Similarly to (1), the lower side of the film configuration shown in Table 2 was bonded to the glass substrate.

### IC for Evaluation of Conduction Properties

External shape: 1.8×20.0 mm

Thickness: 0.3 mm

Au-plated bump: size: 30 μm×85 μm, distance between bumps: 50 μm, bump height: 5 μm

### Glass Substrate (ITO Wiring Glass Substrate)

Thickness: 0.3 mm

### Initial Conduction Resistance Evaluation Criteria

OK: less than 2.0 Ω

NG: 2.0Ω or more

### (4) Conduction Reliability (85° C., 85% RH, 500 Hours)

Similarly to the initial conduction resistance, the conduction resistance of the connection body for evaluation produced in (3) was measured after the connection body had been placed in a constant temperature bath at a temperature of 85° C. and a humidity of 85% RH for 500 hours, and then evaluated in accordance with the following criteria.

### Conduction Reliability Evaluation Criteria

OK: less than 5.0 Ω

NG: 5.0Ω or more

TABLE 1
(part by mass)

| | | | High- | Low- |
|---|---|---|---|---|
| | | | Viscosity | Viscosity |
| | | | Resin Layer- | Resin Layer- |
| | | | Forming | Forming |
| | | | Composition | Composition |
| Phenoxy | Nippon Steel | YP-50 | 22 | 30 |
| Resin | & Sumikin | | | |
| | Chemical | | | |
| | Co., Ltd. | | | |
| Silica | Nippon | Aerosil | 33 | 5 |
| Filler | Aerosil | R805 | | |
| | Co., Ltd. | | | |
| Liquid | Mitsubishi | jER828 | 40 | 60 |
| Epoxy | Chemical | | | |
| | Corporation | | | |
| Silane | Shin-Etsu | KBM-403 | 2 | 2 |
| Coupling | Chemical | | | |
| Agent | Co., Ltd. | | | |
| Thermal | Sanshin | SI-60L | 3 | 3 |
| Cationic | Chemical | | | |
| Polymerization | Industry | | | |
| Initiator | Co., Ltd. | | | |

As seen from Table 2, (2) the adhesiveness of the film surface (temporary pressure bonding test) in Examples 1 to 4 is more excellent than that in Comparative Example 1.

Further, (3) the initial conduction resistance and (4) the conduction reliability in Examples 1 to 4 and Comparative Example 1 are not problematic.

In Examples 1 to 4 and Comparative Example 1, the proportion of the repeat pitch after thermocompression bonding to that before thermocompression bonding with respect to both the A axis and the B axis ((P1/P0)×100%) was 300% or less. Therefore, less disorder of the arrangement before and after thermocompression bonding was confirmed.

### (5) Connection Test by Two-Stage Pushing

An influence of connection by two-stage pushing on holding fillers in the filler-containing film of the present invention was examined. A connection body was produced by two-stage pushing using the anisotropic conductive film of each of Examples 1 to 4 and the following IC chip for evaluation and the following glass substrate as connection objects, and the number of conductive particles held between bumps of the connection body was measured.

### IC Chip for Evaluation

### Peripheral IC Chip

External shape: 6×6 mm

Bump specification: diameter: 36 μm (circular bump), bump pitch: 300 μm

The bump height was higher than the film thickness by 3 μm or more.

### Glass Substrate

### Plate Glass

External shape: 15×15 mm, thickness: 150 μm

Bumps and terminal patterns of the IC chip for evaluation correspond to those of the glass substrate. When the IC chip for evaluation was connected to the glass substrate, a long-side direction of the anisotropic conductive film was matched with a bump arrangement direction. Pressing for temporary pressure bonding in two-stage pushing was performed at 80° C. for 3 seconds, and pressing for final pressure bonding was performed at 180° C. and a pressure that was twice the pressure for the temporary pressure bonding for 10 seconds. In performing a process from the temporary pressure bonding to the final pressure bonding, the pressure applied to the IC chip for evaluation was increased without being released. As a bonder, a flip chip bonder (FCB3 manufactured by Panasonic Corporation, provided with a pulse heater) was used. In both the temporary pressure bonding and the final pressure bonding, the temperature was increased for 0.5 seconds, and the pressure was increased for 0.5 seconds.

For comparison, a connection body was produced by performing only final pressure bonding described above without pressing in temporary pressure bonding.

The conductive particles held between the bumps after the final pressure bonding were counted. It was confirmed that the number of the held conductive particles per bump in the connection body obtained by two-stage pushing (after temporary pressure bonding, the pressure was increased without being released) was larger than that in the connection body obtained without pressing in temporary pressure bonding.

### REFERENCE SIGNS LIST

1, 1A, 1B, 1C, 1D, 1E filler-containing film, anisotropic conductive film
2 filler, conductive particle
3 fine solid
10, 11, 12 insulating resin layer
10a, 11a, 12a dried surface
10b, 11b, 12b surface of insulating resin layer on release substrate side
15 low-viscosity resin layer
15a dried surface of low-viscosity resin layer
15b surface opposite to dried surface of low-viscosity resin layer
20a, 20b, 20c release substrate
21 mold
30, 31 glass slide
D particle diameter of filler

1. A filler-containing film that holds fillers and a fine solid that is made of a material different from that of the filler in an insulating resin layer and in which a predetermined arrangement of the fillers is repeated as viewed in a plan view, wherein
a proportion of a repeat pitch of the fillers after thermocompression bonding to that before thermocompression bonding during thermocompression bonding under a predetermined thermocompression bonding condition with the filler-containing film held between smooth surfaces is 300% or less.

2. The filler-containing film according to claim 1, wherein the insulating resin layer is formed from a layered body of two insulating resin layers.

3. The filler-containing film according to claim 1, wherein a low-viscosity resin layer having a lowest melt viscosity at a range of 30 to 200° C. that is lower than that of the insulating resin layer is layered on the insulating resin layer.

4. A method of producing the filler-containing film according to claim 1, comprising the steps of:
applying an insulating resin layer-forming composition containing a fine solid to a release substrate to form an insulating resin layer on the release substrate;
pushing fillers from a surface on a side opposite to the release substrate of the insulating resin layer; and
layering the insulating resin layer containing the fillers pushed and another insulating resin layer that is different from the insulating resin layer with the release substrates thereof facing outward.

5. The method of producing the filler-containing film according to claim 1, comprising the steps of:
applying an insulating resin layer-forming composition containing a fine solid to a release substrate to form an insulating resin layer on the release substrate;
layering two insulating resin layers with the release substrates thereof facing outward to form a layered body of the insulating resin layers; and
pushing fillers into the layered body of the insulating resin layers.

6. The method of producing the filler-containing film according to claim 3, comprising the steps of:
applying an insulating resin layer-forming composition containing a fine solid to a release substrate to form an insulating resin layer on the release substrate;
applying a composition for formation of a low-viscosity resin layer having a lowest melt viscosity at a range of 30 to 200° C. that is lower than that of the insulating resin layer to a release substrate to form a low-viscosity resin layer on the release substrate;
layering the insulating resin layer and the low-viscosity resin layer with the release substrates thereof facing outward to form a layered body of the insulating resin layer and the low-viscosity resin layer; and
peeling the release substrate of the insulating resin layer and pushing fillers from a surface of the insulating resin layer from which the release substrate has been peeled.

7. The method of producing the filler-containing film according to claim 3, comprising the steps of:
applying an insulating resin layer-forming composition containing a fine solid to a release substrate to form an insulating resin layer on the release substrate;
applying a composition for formation of a low-viscosity resin layer having a lowest melt viscosity at a range of 30 to 200° C. that is lower than that of the insulating resin layer to a release substrate to form a low-viscosity resin layer on the release substrate;
pushing fillers into a surface on a side opposite to the release substrate of the insulating resin layer; and
layering the insulating resin layer containing the fillers pushed and the low-viscosity resin layer formed on the release substrate with the release substrates thereof facing outward.

8. A film-bonded body in which the filler-containing film according to claim 1 is bonded to an article.

9. A connection body in which a first article and a second article are connected to each other through the filler-containing film according to claim 1.

10. The connection body in which a first electronic component and a second electronic component are connected to each other through an anisotropic conductive film obtained by using conductive particles as the fillers in the filler-containing film according to claim 1.

11. A method of producing a connection body, comprising connecting a first article and a second article to each other through the filler-containing film according to claim 1.

12. The method of producing a connection body, comprising connecting a first electronic component and a second electronic component to each other through an anisotropic conductive film obtained by using conductive particles as the fillers in the filler-containing film according to claim 1.
